(19) United States
(12) Patent Application Publication
(10) Pub. No.: US 2025/0372457 A1
(43) Pub. Date: Dec. 4, 2025

(54) METHOD FOR PROCESSING A WAFER AND METHOD FOR MANUFACTURING DEVICE CHIPS

(71) Applicant: DISCO CORPORATION, Tokyo (JP)

(72) Inventors: Yoshinobu SAITO, Tokyo (JP); Jonghyun RYU, Tokyo (JP)

(73) Assignee: DISCO CORPORATION, Tokyo (JP)

(21) Appl. No.: 19/214,254

(22) Filed: May 21, 2025

(30) Foreign Application Priority Data
May 29, 2024 (JP) 2024-087086

(51) Int. Cl. H01L 21/66; H01L 21/683; H01L 21/78

(52) U.S. Cl. CPC H01L 22/12; H01L 21/6836; H01L 21/78; H01L 2221/68327

(57) ABSTRACT

A processing method for processing a wafer, on a surface on one side of which a recess and a ring-shaped protrusion surrounding the recess are formed, the surface having a protective member being fixed thereon, is provided. The processing method includes holding the one side of the wafer against a holder table, forming a protective film in a region including a boundary between the recess and the protrusion on the wafer held on the holder table, inspecting the protective film formed on the wafer, and cutting the wafer along the boundary, in a case where the protective film passes the inspection, by irradiating the boundary with a laser beam.

### CROSS REFERENCE TO RELATED APPLICATION

This application is based upon and claims the benefit of priority from the prior Japanese Patent Application No. 2024-087086 filed on May 29, 2024; the entire contents of which are incorporated herein by reference.

### FIELD

The present disclosure relates to a method for processing a wafer and a method for manufacturing device chips.

### BACKGROUND

In recent years, wafers, of which rigidity is ensured by forming a reinforcing annular protrusion in an outer peripheral margin region surrounding a device region, have been suggested. In such wafers, the annular protrusion is removed during a process for manufacturing chips by laser ablation. Meanwhile, debris generated during the ablation and adhering to the surface of the wafer has been a problem.

Technologies related to such a problem are disclosed in, for example, in Japanese Patent Application Laid-Open Patent Publications No. 2022-114113 and No. 2004-322168. According to these publications, a region of the wafer to be irradiated with the laser beam may be covered with a protective film in advance.

### SUMMARY

However, when the protective film is not formed on the wafer properly, debris may still adhere to the surface of the wafer. In view of such difficulties, the present disclosure is made and provides a method for processing a wafer and a method for manufacturing device chips, by which adherence of debris to the wafer may be reduced.

A processing method for processing a wafer, on a surface on one side of which a recess and a ring-shaped protrusion surrounding the recess are formed, the surface having a protective member being fixed thereon, is provided. The processing method includes holding the one side of the wafer against a holder table, forming a protective film in a region including a boundary between the recess and the protrusion on the wafer held on the holder table, inspecting the protective film formed on the wafer, and cutting the wafer along the boundary, in a case where the protective film passes the inspection, by irradiating the boundary with a laser beam.

A manufacturing method for manufacturing a plurality of device chips is provided. The manufacturing method includes holding one side of a wafer against a holder table, the wafer including a surface on the one side thereof, the surface having a recess and a ring-shaped protrusion surrounding the recess being formed thereon and a protective member being fixed thereon; forming a protective film in a region including a boundary between the recess and the protrusion on the wafer held on the holder table; inspecting the protective film formed on the wafer; cutting the wafer along the boundary, in a case where the protective film passes the inspection, by irradiating the boundary with a laser beam; and dicing a region corresponding to the recess in the wafer into the plurality of device chips after cutting the wafer along the boundary.

According to the method for processing a wafer and the method for manufacturing device chips in the present disclosure, adherence of debris to the wafer may be reduced.

### BRIEF DESCRIPTION OF THE DRAWINGS

FIG. 1 is a flowchart illustrating a method for manufacturing device chips according to a first embodiment.

FIG. 2 is an exemplary perspective view of a front surface of a wafer.

FIG. 3 is an exemplary perspective view of a back surface of the wafer.

FIG. 4 is a diagram illustrating a holding step and a protective film forming step.

FIG. 5 is a perspective view of a frame unit including the wafer with the protective film formed thereon.

FIG. 6 is a diagram illustrating an inspection step.

FIG. 7A is an illustrative view of an image captured in the inspection step.

FIG. 7B is another illustrative view of an image captured in the inspection step.

FIG. 7C is another illustrative view of an image captured in the inspection step.

FIG. 8 is a diagram illustrating a drying step.

FIG. 9 is a diagram illustrating a cutting step.

FIG. 10A is a diagram illustrating a ring removal step.

FIG. 10B is another diagram illustrating the ring removal step.

FIG. 11 is a diagram illustrating a dicing step.

FIG. 12 is a flowchart illustrating a method for manufacturing device chips according to a second embodiment.

FIG. 13 is a flowchart illustrating a method for manufacturing device chips according to a third embodiment.

### DESCRIPTION OF EMBODIMENTS

### First Embodiment

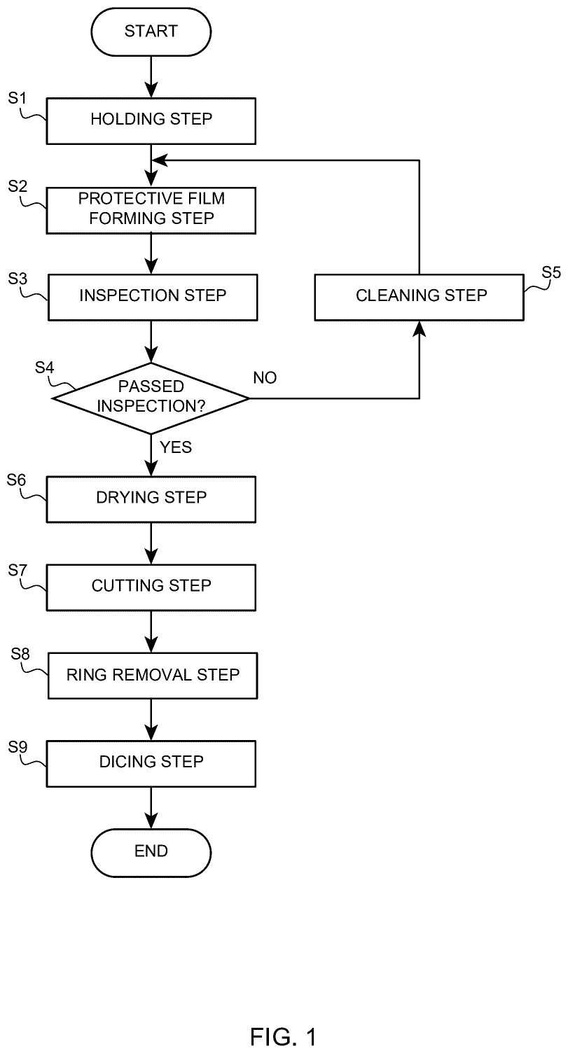

FIG. 1 is a flowchart illustrating a method for manufacturing device chips according to a first embodiment. FIG. 1 shows a method for manufacturing device chips by dicing a wafer, having been processed in a method for processing a wafer according to the present embodiment. Steps S1 through S7 in the method for manufacturing device chips according to the present embodiment compose the method for processing a wafer of the present embodiment.

The wafer to be used in the present embodiment may be, for example, a wafer processed through TAIKO (registered trademark) grinding process. TAIKO grinding refers to a grinding process to form an annular protrusion in an outer peripheral region of the wafer by thinning a central region while leaving the outer peripheral region intact. With TAIKO grinding, the thinned wafer is reinforced by the annular protrusion, which may therefore prevent deformation of the wafer compared to a wafer without the protrusion. Hereinafter, the annular protrusion (the ring-shaped protrusion) formed in the outer peripheral region of the wafer is referred to as a ring-shaped reinforcement portion.

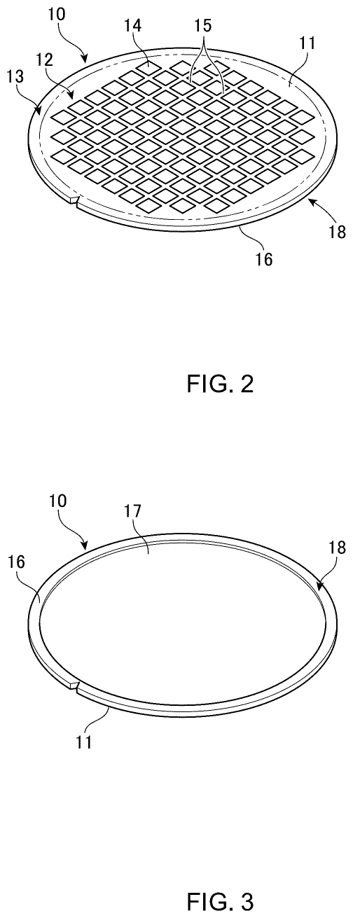

FIG. 2 is an exemplary perspective view of a front surface 11 of a wafer 10. On the front surface 11 of the wafer 10, a device region 12 in which plurality of devices 14 are formed is provided. The device region 12 is divided by plurality of predetermined dicing lines 15. Further, on an outer periphery of the device region 12, a peripheral margin region 13, in which the devices 14 are not formed, is provided. In other words, the front surface 11 of the wafer 10 includes the device region 12 and the peripheral margin region 13 surrounding the device region 12.

FIG. 3 is an exemplary perspective view of a back surface 16 of the wafer 10. In TAIKO grinding, since a central region of the back surface 16 of the wafer 10 is ground to be thinned, a recess 17 is formed on the back surface 16, as shown in FIG. 3. As the recess 17 is formed, a ring-shaped reinforcement portion 18 maintaining the thickness as before grinding is formed on an outer periphery of the recess 17. The ring-shaped reinforcement portion 18 is formed in the region of the back surface 16 corresponding to the peripheral margin region 13 of the front surface 11. In other words, the back surface 16 is the surface on one side of the wafer 10 of which the recess 17 and the ring-shaped reinforcement portion 18 (the ring-shaped protrusion) are formed. The back surface 16 may also be called a first surface of the wafer 10 and the front surface 11 may also be called a second surface of the wafer 10.

Hereinafter, the method for manufacturing device chips shown in FIG. 1 and the method for processing a wafer, which is performed within the method for manufacturing device chips, will be described. Optionally, the method for manufacturing device chips may be performed by a single apparatus including multiple units for executing respective steps, or may be distributed to be performed by multiple apparatuses.

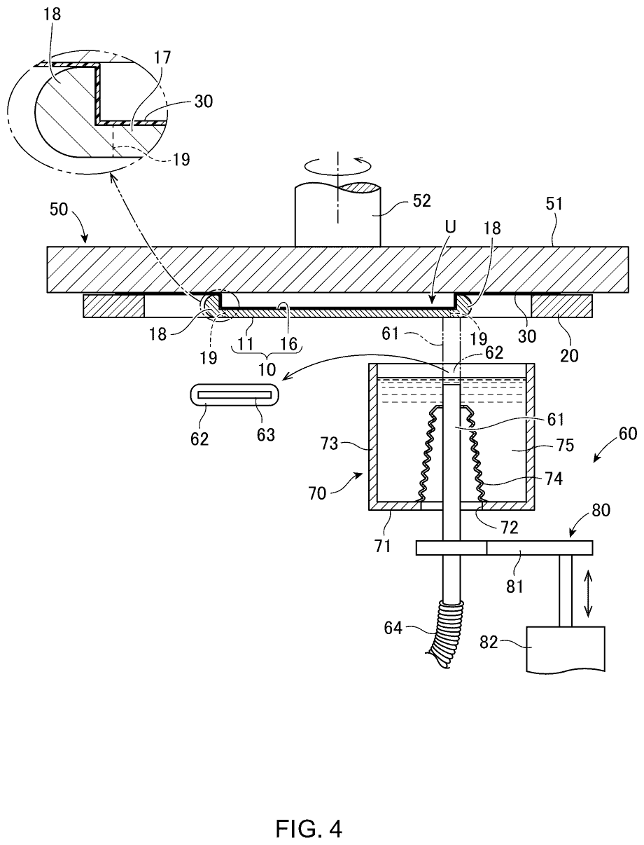

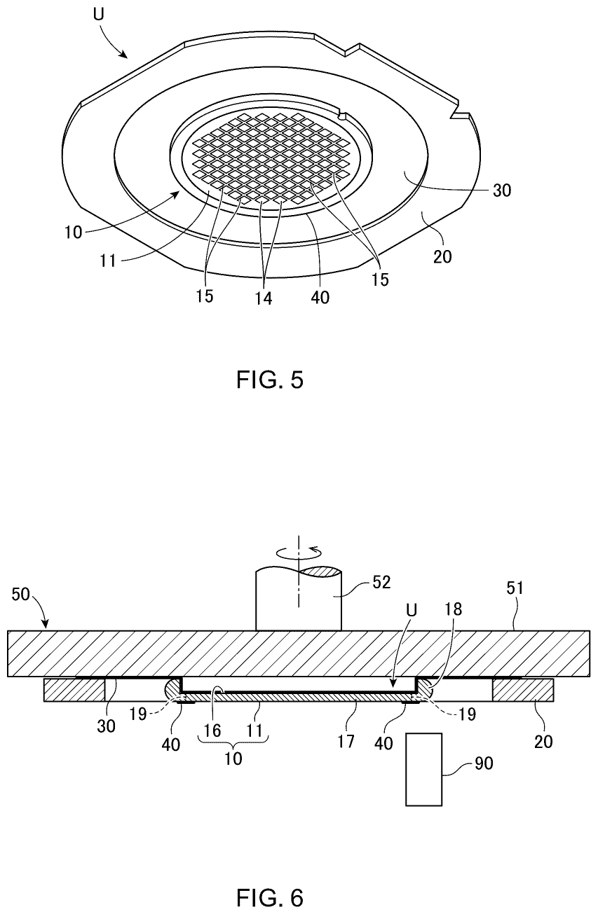

FIG. 4 is diagram illustrating a holding step and a protective film forming step. FIG. 5 is a perspective view of a frame unit U including the wafer 10 with the protective film (the protective coat) formed thereon. When a process for manufacturing the device chips using the method shown in FIG. 1 is started, first, the holding step and the protective film forming step are performed (Step S1, Step S2).

In the holding step in Step S1, as shown in FIG. 4, in preparation for the protective film forming step in Step S2, in which a protective film is formed on the front surface 11 of the wafer 10, the back surface 16 of the wafer 10 is held on a holder table 50. The back surface 16 is the surface opposite to the front surface 11 where the protective film is to be formed. The holder table 50 includes a holder portion 51, which is rotatable around a support shaft 52, and in the holding step, the wafer 10 is suctioned to be held against a lower surface of the holder portion 51.

In the holding step, the wafer 10 is handled as a part of a frame unit U to be conveyed to the holder table 50. More specifically, the wafer 10 is conveyed to the holder table 50 with a tape 30 being a protective member fixed to the back surface 16. The back surface 16 is the surface of the wafer 10 through which the wafer 10 is held by the holder table 50. As shown in FIG. 5, the frame unit U is composed of an annular frame 20 and the wafer 10, where the wafer 10 is attached to the frame 20 with the tape 30 that closes an opening of the frame 20. It should be noted that a protective film 40 shown in FIG. 5 is a film formed in the protective film forming step which will be described later in detail, and in the holding step, the frame unit U not having the protective film 40 yet is conveyed to the holder table 50.

In the protective film forming step in Step S2, a coating apparatus 60 shown in FIG. 4 forms the protective film is formed on the wafer 10 held on the holder table 50. The protective film formed in the protective film forming step serves to prevent debris generated in a cutting step (Step S7), which will be described below, from adhering to wafer 10.

Therefore, in the protective film forming step, it is preferable to form the protective film on a region of wafer 10 where debris may be generated or adhere. Specifically, in the cutting step, a boundary between the recess 17 and the ring-shaped reinforcement portion 18 being a protrusion is cut with laser; therefore, in the protective film forming step, the protective film may be formed in the region that includes the boundary. That is, the boundary may be described as a region to be irradiated with a laser beam in the cutting step (predetermined cutting line 19), and the region including the boundary may be described as a region including the predetermined cutting line 19.

Accordingly, in the protective film forming step, the protective film is formed in the region that includes the predetermined cutting line 19 of the wafer 10 held on the holder table 50. FIG. 4 illustrates a state in which the protective film is formed in the region that includes the predetermined cutting line 19 on the wafer 10 held on the holder table 50 by the coating apparatus 60. Hereinafter, the region including the predetermined cutting line 19, which is a target for forming the protective film thereon, is referred to as a target region.

The coating apparatus 60 is configured such that a nozzle 61 is fed with a liquid resin through a liquid supply tube 64 by a pump, which is not shown. The liquid resin may be, for example, a water-soluble liquid resin such as polyvinyl alcohol (PVA). An opening 63 at a tip 62 of the nozzle 61 is, as shown in FIG. 4, has a cross-sectional a shape of an elongated slit. The coating apparatus 60 is provided with an immersing container 70 in which the tip 62 of the nozzle 61 is immersed to prevent drying. The immersing container 70 includes a bottom plate 71 having an opening 72, through which the nozzle 61 is inserted, and a side wall 73 extending upward from a peripheral edge of bottom plate 71, and the nozzle 61 is fixed to a position inside the immersing container 70 via a bracket, which is not shown. To prevent leakage of water 75 from the immersing container 70 through the opening 72, a bellows-shaped rubber cover 74 is attached to the bottom plate 71, extending to skew inward and upward from periphery of the opening 72. The coating apparatus 60 is further provided with a lift/lower assembly 80 for moving the nozzle 61 up and down. The lift/lower assembly 80 includes an actuator 82 that lifts or lowers a connecting piece 81, which is connected to the nozzle 61, and when the actuator 82 is driven, the tip 62 of the nozzle 61 is lifted out of the water 75 in the immersing container 70 and is located near the front surface 11 of the wafer 10 held on the holder table 50. Note that the position of the wafer 10 held on the holder table 50 is adjusted in advance such that the predetermined cutting line 19 is located on an extension line of the nozzle 61.

The coating apparatus 60 configured as above may discharge the liquid resin in a state where the nozzle 61 is located near the predetermined cutting line 19 on the front surface 11 of the wafer 10, as shown in FIG. 4, and may form a film of liquid resin, that is, a protective film, on the region of the front surface 11 including the predetermined cutting line 19. Meanwhile, the holder table 50 rotates the holder portion 51 around the support shaft 52, so that coating apparatus 60 may form the protective film over the region including entire annular predetermined cutting line 19 extending along the circumferential direction of wafer 10. FIG. 5 shows the frame unit U including the wafer 10, on the front surface 11 of which the annular protective film 40 is formed.

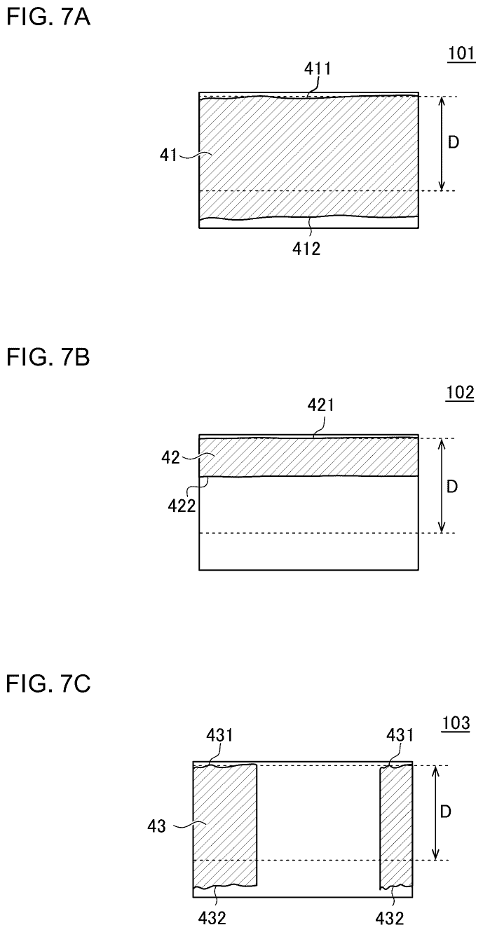

FIG. 6 is a diagram illustrating an inspection step. FIGS. 7A to 7C are illustrative views of images captured in the inspection step. After the protective film forming step in Step S2 is completed, an inspection step for inspecting the protective film 40 formed on the wafer 10 is performed (Step S3).

In the inspection step, as shown in FIG. 6, an image of the front surface 11 of the wafer 10 is acquired by an image capturing unit 90 arranged on a side of the front surface 11 of the wafer 10, and the protective film 40 is inspected based on the acquired image. For example, whether the protective film 40 is formed in a region (target region), where the wafer 10 requires the protective film 40 to prevent adherence of debris, may be inspected. The target region is defined with reference to the predetermined cutting line 19 (boundary), at which the laser beam is emitted, and is preferably defined in a format that may specify the region on the image acquired in the inspection step. For example, the target region may be defined as a region ranging in a certain number of millimeters inward from an edge of the wafer 10 (the front surface 11). Hereinafter, an example, in which the target region is defined as a region ranging from 0 mm (i.e., starting from the edge) to D mm inward in the radial direction from the edge, is described.

On the image acquired by the image capturing unit 90, brightness is largely different between the region where the protective film 40 is formed and the other regions (regions on the wafer 10 where the protective film 40 is not formed and regions outside the wafer 10). Therefore, in the inspection step, whether the protective film 40 is formed in the target region may be inspected by connecting points where the brightness is different largely in the image to a line and detecting an edge of the protective film 40 based on the line.

For example, in a case where the protective film 40 covering at least a vicinity of an edge of the front surface 11 of the wafer 10 is formed earlier in the protective film forming step, an edge of the protective film 40 located on the radially outside of the wafer 10, among the edges of the protective film 40 detected in the image, may be determined as the edge of the front surface 11. Therefore, whether the protective film 40 is formed in the target region may be inspected by comparing the radial distance (D mm in this example) between the outer edge and inner edge of the protective film 40 with a width of the target region. In this case, for example, as shown in an image 101 in FIG. 7A, if the distance between an outer edge 411 and an inner edge 412 of the protective film 41 covers the width D of the target region, it may be determined that the protective film 41 is formed in the target region. As shown in an image 102 in FIG. 7B, if the distance between an outer edge 421 and an inner edge 422 of the protective film 42 is smaller than the width D of the target region, it may be determined that the protective film 42 is not sufficiently formed in the target region. Furthermore, as shown in an image 103 in FIG. 7C, even if the distance between an outer edge 431 and an inner edge 432 of the protective film 43 covers the width D of the target region, as the protective film 43 is discontinued in the circumferential direction of the wafer 10, it may be determined that the protective film 43 is not sufficiently formed in the target region.

In a case where the protective film 40 is not necessarily formed near the edge of the front surface 11 of the wafer 10 in the protective film forming step, the edge of the protective film 40 and the edge of the front surface 11 of the wafer 10 may be detected from the image, and based on the detected edges of the protective film 40 and the front surface 11, whether the protective film 40 is formed in the target region may be inspected. A method for detecting the edge of the front surface 11 of the wafer 10 is not necessarily limited, but the edge of the front surface 11 may be detected based on the brightness difference between a region on the wafer 10 and a region outside the wafer 10.

In the inspection step, while the wafer 10 on the holder table 50 is rotated, it is referable that multiple images are acquired by capturing different circumferential regions of the wafer 10 with the image capturing unit 90, and inspect each of the acquired images in the method described above.

In the inspection as described above, if any defect is found, such as insufficient width of the protective film, discontinuity in the circumferential direction, or partially uncoated areas in the target region, and the protective film does not pass the inspection (Step S4: NO), a cleaning step (Step S5) is performed to wash the protective film off from the front surface 11, and thereafter, the process as described above is repeated again starting from the protective film forming step. Optionally, the cleaning step may be omitted, and in the case where the protective film does not pass the inspection, a new protective film may be formed over the partially formed protective film in the protective film forming step.

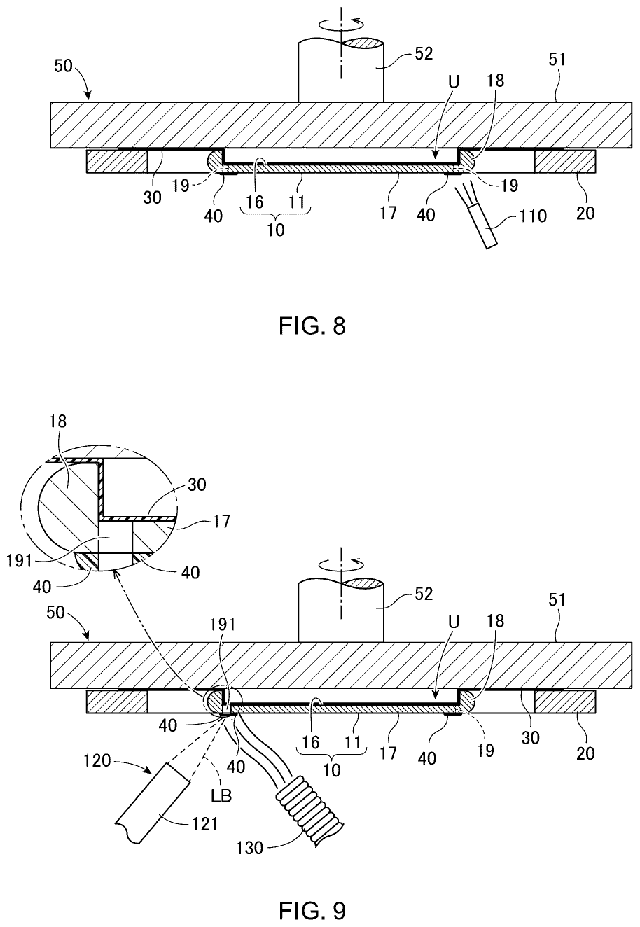

FIG. 8 is a diagram illustrating a drying step. If the protective film passes the inspection (Step S4: YES), a drying step (Step S6) to dry the protective film 40 formed on the wafer 10 is performed.

In the drying step, as shown in FIG. 8, while the wafer 10 on the holder table 50 is rotated, a gas such as air is supplied to the protective film 40 formed on the front surface 11 of the wafer 10 by an air supply unit 110 arranged on the side of the front surface 11, thereby drying the protective film 40.

The air supply unit 110 is configured to supply the gas radially from the outer side toward the inner side of the wafer 10. This is to prevent the protective film 40, which has fluidity before drying, from moving radially outward on the front surface 11 of the wafer 10 and extending over the edge of the front surface 11 to the side surface of the wafer 10 during the drying step. As such, inconveniences, which may be caused by the protective film 40 wrapping around the side surface of the wafer 10, and which may occur particularly in a ring removal step described later, may be prevented in advance. Moreover, adherence of debris should particularly be prevented more strictly on the side of the recess 17 (the radially inner side), which forms a final product, than on the side of the ring-shaped reinforcement portion 18 (the radially outer side). Therefore, it is preferable that the gas be supplied from the outside toward the inside. However, as long as the protective film 40 does not wrap around the side surface of the wafer 10, the air supply unit 110 may supply the gas in any direction to dry the protective film 40.

FIG. 9 is diagram illustrating a cutting step. After the drying step is completed, a cutting step (Step S7) is performed to cut the wafer 10.

In the cutting step, as shown in FIG. 9, while the wafer 10 on the holder table 50 is rotated, a laser beam LB is emitted at the predetermined cutting line 19 from the side of the front surface 11 of the wafer 10 through a condenser 121 in a laser unit 120, and the wafer 10 is cut along the predetermined cutting line 19 by ablation.

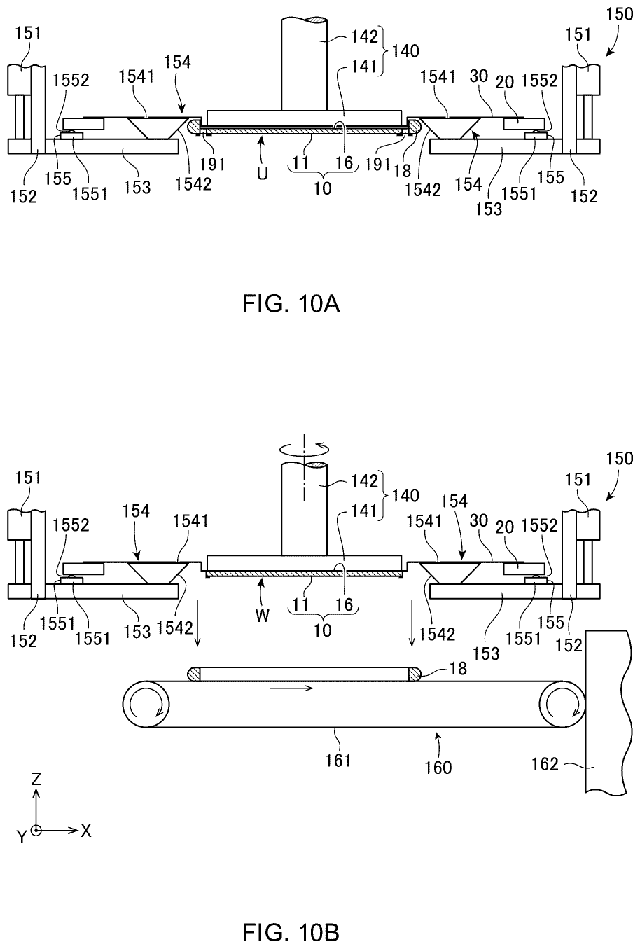

As a result, a cutting groove 191 in a ring shape is formed in a portion corresponding to the predetermined cutting line 19, and the wafer 10 is separated into a circular wafer W (scc FIGS. 10A and 10B) including the recess 17 on the back surface 16 and the device region 12 on the front surface 11, and an annular member including the ring-shaped reinforcement portion 18 on the back surface 16 and the peripheral margin region 13 on the front surface 11. Moreover, by locating a suction nozzle 130 near a focal point of the laser beam LB, some of the debris generated by ablation is sucked through the suction nozzle 130, while the remaining debris may adhere to the protective film 40 formed in the target region including the predetermined cutting line 19. As such, a situation such that the debris generated in the cutting step adheres directly to the front surface of the wafer 10 may be prevented.

FIGS. 10A and 10B are diagrams illustrating a ring removal step. After the cutting step is completed, a ring removal step (Step S8) is performed to remove the ring-shaped reinforcement portion 18 having been separated from the recess 17.

The ring removal step includes a separating step, in which spinners 154 being a separating member are inserted between the tape 30 in the frame unit U and the ring-shaped reinforcement portion 18 using a holder table 140 and a separating device 150, and the ring-shaped reinforcement portion 18 is separated from the tape 30, as shown in FIGS. 10A and 10B. By separating the ring-shaped reinforcement portion 18 from the tape 30, the portion including the ring-shaped reinforcement portion 18 separated by the cutting groove 191 from the wafer W including the device region 12 is removed, and the wafer W including the device region 12 corresponding to the recess 17 is achieved.

The holder table 140 includes a holder portion 141 which is rotatable around a support shaft 142, and in the ring removal step, the recess 17 (back surface 16) is suctioned to hold the wafer 10 against a lower surface of the holder portion 141. In the meantime, the frame 20 of the frame unit U is supported by a frame support portion 155. The separating device 150 includes the frame support portion 155 on a support board 153, which is connected to a movable piece 152 movable in a Z-axis direction to be lifted or lowered by a feeder unit 151. The frame support portion 155 includes housings 1551 and spheres 1552, which are each rollably supported by the housing 1551 supporting the frame 20. The separating device 150 further includes a pair of spinners 154 on the support board 153. Each spinner 154 has an inverted truncated cone shape, with a bottom surface smaller than the top surface 1541, and is supported on the support board 153 rotatably around a rotation axis extending in the Z-axis direction. The pair of spinners 154 are configured to be movable toward or away from each other by a feeder unit, which is not shown.

In the ring removal step, as shown in FIG. 10A, the feeder unit 151 is controlled such that an upper end of the ring-shaped reinforcement portion 18 of the wafer 10 held by the separating device 150 aligns approximately with top surfaces 1541 of the spinners 154, and further, by moving the spinners 154 closer to each other, side surfaces 1542 of the spinners 154 are inserted between the tape 30 and the ring-shaped reinforcement portion 18. As a result, as shown in FIG. 10B, the ring-shaped reinforcement portion 18 is released from the tape 30, and the portion of the wafer 10 including the ring-shaped reinforcement portion 18 falls into a disposer unit 160. The portion including the ring-shaped reinforcement portion 18 fallen into the disposer unit 160 is conveyed to a waste box 162 by a belt conveyor 161.

In a case where the protective film adheres to the side surface of the wafer 10 (the portion including the ring-shaped reinforcement portion 18), the protective film may also adhere to the spinner(s) 154. When the protective film adheres to the spinner(s) 154, an excessive localized force may be applied undesirably to the wafer 10 as the spinners 154 are being inserted. Moreover, when the spinners 154 are inserted, the protective film wrapped around the side surface of the wafer 10 may fall off, and debris generated by the impact of the fall may scatter within the apparatus and may adhere to unintended regions in the wafer W to contaminate the wafer W. The configuration in which the gas is supplied radially inward from the outside in the drying step described above is preferable in avoiding such inconveniences.

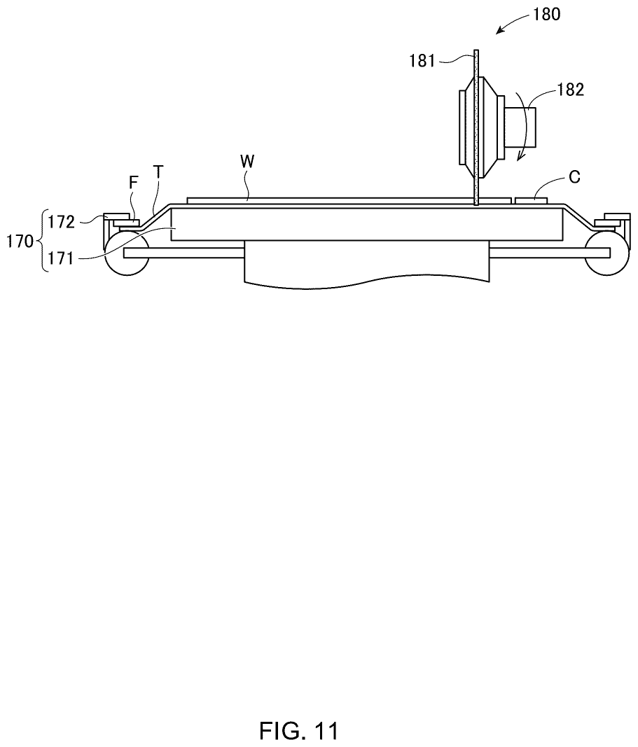

FIG. 11 is a diagram illustrating a dicing step. After the ring removal step is completed, a dicing step (Step S9) is performed to dice the wafer W obtained in the ring removal step into a plurality of device chips.

In the dicing step, first, another frame unit U, in which the wafer W acquired in the ring removal step is integrated with the frame F with a tape T, is assembled, and the frame unit U is held on a holder table 170. More specifically, as shown in FIG. 11, with a frame holder 172 clamping the frame F, the wafer W is suctioned and held via the tape T on a wafer holder 171. Next, the wafer W is diced into a plurality of chips C by a cutting unit 180. More specifically, the wafer W is cut along the predetermined dicing lines 15 (see FIG. 2) with a cutting blade 181 rotating around a spindle 182. As such, the plurality of chips C are manufactured.

As described above, according to the method for processing a wafer and the method for manufacturing device chips according to the present embodiment, the wafer is cut by laser after verifying that the protective film is formed in the target region through the inspection. Therefore, potential problems associated with adherence of debris may be avoided.

### Second Embodiment

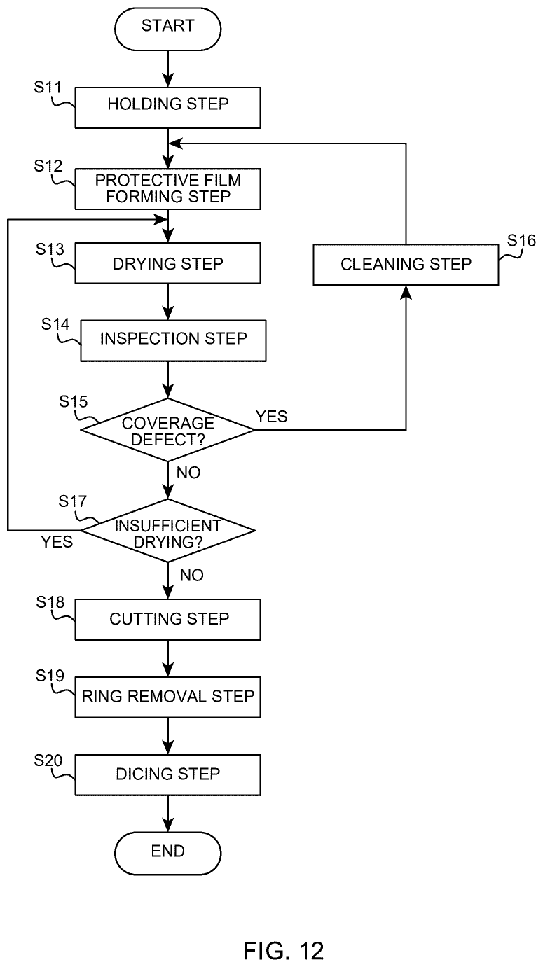

FIG. 12 is a flowchart illustrating a method for manufacturing device chips according to a second embodiment. The method for manufacturing device chips according to the present embodiment as shown in FIG. 12 is a method to manufacture device chips by dicing a wafer processed in the method for processing a wafer according to the present embodiment. Steps S11 through S18 of the method for manufacturing device chips includes the method for processing a wafer according to the present embodiment.

The method for manufacturing device chips according to the present embodiment is the same as the method according to the first embodiment in that the cutting step is performed after the protective film passed the inspection in the inspection step. On the other hand, the method for manufacturing device chips according to the present embodiment is different from the method for manufacturing device chip in the first embodiment in that the inspection step is performed after the drying step. The method for manufacturing device chips of the present embodiment and the method for processing a wafer to be performed during the process of manufacturing the device chips will be described focusing on this difference.

When a device chip manufacturing process applying the method for manufacturing device chips as shown in FIG. 12 is started, first, a holding step and a protective film forming step are performed (Steps S11 and S12). The processes to be performed in the holding step and protective film forming step are as described in the first embodiment with reference to FIG. 4. Next, a drying step is performed (Step S13). The process to be performed in the drying step is as described in the first embodiment with reference to FIG. 8.

After the drying step is completed, an inspection step is performed (Step S14). In the inspection step, images of the front surface 11 of the wafer 10 are acquired by the image capturing unit 90 arranged on the side of the front surface 11, and the protective film 40 is inspected based on the acquired images, similarly to the inspection step described in the first embodiment with reference to FIG. 6. However, the content to be inspected is different.

In the inspection step according to the present embodiment, further to the inspection performed in the first embodiment (Step S3 in FIG. 1) to determine whether the protective film 40 is formed in the target region, whether the protective film 40 has dried is inspected. This is because the protective film 40 being dried may be prevented from moving, being deformed, or falling, and it is preferable in that the inspection may ensure the protective film is formed in the target region at the time when the cutting step is performed.

Whether the protective film 40 is dry or not may be determined, in a case where the image capturing unit 90 is a color camera, based on detection of interference fringes. If the protective film 40 is not dried but remains wet, a surface height of the protective film 40 is substantially flat, and interference fringes are not likely to appear. In contrast, if the protective film 40 is sufficiently dried in the drying step, the thickness of the protective film 40 may vary due to collision with the gas, making interference fringes more likely to occur. More specifically, in regions closer to the air supply unit 110 being the gas supply source, a rate of the gas flow is higher, and the gas collides with the protective film 40 with greater force, thereby reducing the thickness of the protective film 40. In contrast, as the distance from the air supply unit 110 increases, the rate of the gas flow decreases, and the gas collides with the protective film 40 with less force. Accordingly, reduction of the thickness of the protective film is moderated, and the protective film 40 is thickened compared to the part of the protective film closer to the air supply unit 110. As such, the dried protective film 40 exhibits slight thickness variations depending on the location, and these variations cause interference fringes. Since the likelihood of interference fringe formation differs between a dried portion and a wet portion, whether the protective film 40 is dry or not may be determined by detecting interference fringes from color images acquired by the color camera. Note that the protective film 40 formed on the front surface 11 is not necessarily dried entirely; however, it is desirable that the protective film 40 formed in the target region be dried. Therefore, in the inspection step, it is preferable to inspect, through an imaging process, whether the region in which interference fringes appear covers the target region.

If the protective film fails the inspection due to a coverage defect such that the protective film 40 is not formed in the target region (Step S15: YES), a cleaning step (Step S16) is performed to wash the protective film formed on the front surface 11, and thereafter, the process as described above is repeated from the protective film forming step. Optionally, the cleaning step may be omitted, and if the inspection fails, a new protective film may be formed over the partially formed protective film in the protective film forming step. Meanwhile, if the inspection fails due to insufficient drying of the protective film 40 (Step S17: YES), the processing described above is repeated from the drying step. In other words, the drying time may be extended.

When the protective film passes the inspection (Step S17: NO), a cutting step (Step $18), a ring removal step (Step S19), and a dicing step (Step S20) are performed to manufacture device chips. The processes in Steps S18 through S20 are the same as those in Steps S7 through S9 shown in FIG. 1.

As described above, according to the method for processing a wafer and the method for manufacturing device chips of the present embodiment, the wafer is cut by laser after formation of the protective film in the target region is confirmed and the formed protective film is sufficiently dried. Accordingly, adhesion of debris generated by laser ablation to the wafer may be prevented more reliably.

### Third Embodiment

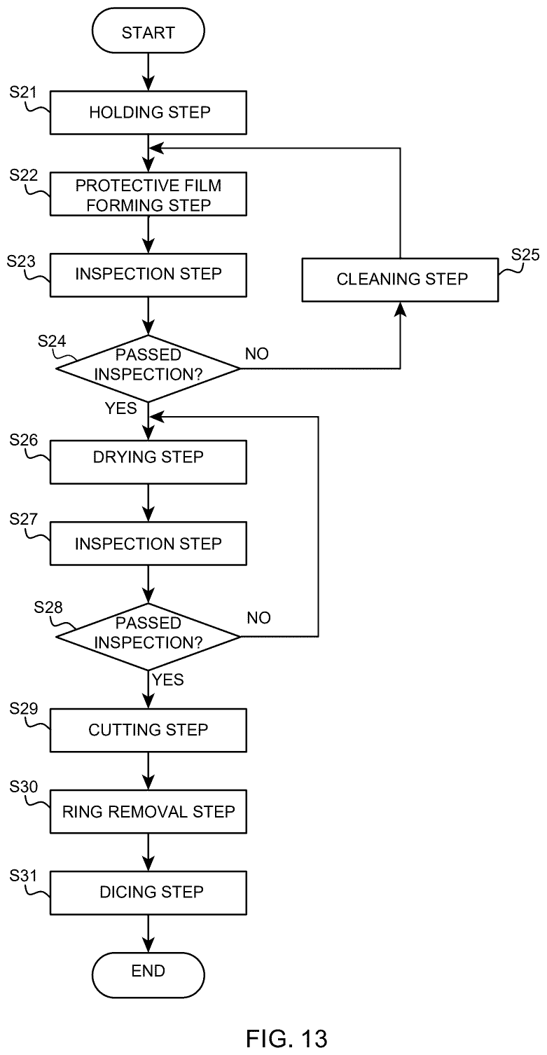

FIG. 13 is a flowchart illustrating a method for manufacturing device chips according to a third embodiment. The method for manufacturing device chips according to the present embodiment shown in FIG. 13 is a method for manufacturing device chips by dicing a wafer processed in the method for processing a wafer according to the present embodiment. Steps S21 through S29 in the method for manufacturing device chips compose the method for processing a wafer according to the present embodiment.

The method for manufacturing device chips according to the present embodiment is the same as the method according to the embodiments described above in that the cutting step is performed after the protective film passed the inspection in the inspection step. On the other hand, the method for manufacturing device chips according to the present embodiment is different from the method according to the embodiments described above in that the inspection step is performed each time after the protective film forming step and the drying step. The method for manufacturing device chips of the present embodiment and the method for processing a wafer to be performed during the process of manufacturing the device chips will be described focusing on this difference.

The processes in Steps S21 through S26 shown in FIG. 13 are the same as those in Steps S1 through S6 shown in FIG. 1. After the drying step in Step S26 is completed, an inspection step is performed to inspect whether the protective film 40 is dried (Step S27). The inspection performed in Step S27 is the same as the inspection of Step S14 in FIG. 12, in which whether the protective film 40 is dried is inspected.

If the protective film 40 is not sufficiently dried and does not pass the inspection in Step S27 (Step S28: NO), the process described above is repeated from the drying step. In other words, the drying time is extended.

When the protective film passes the inspection (Step S28: YES), a cutting step (Step S29), a ring removal step (Step S30), and a dicing step (Step S31) are performed to manufacture device chips. The processes in Steps S18 through S20 are the same as those in Steps S7 through S9 shown in FIG. 1. The processes in Steps S29 through S31 are the same as those in Steps S7 through S9 shown in FIG. 1.

As described above, according to the method for processing a wafer and the method for manufacturing device chips of the present embodiment, similarly to the second embodiment, the wafer is cut by laser after formation of the protective film in the target region is confirmed and sufficient dryness of the formed protective is confirmed. Accordingly, adhesion of debris generated by laser ablation to the wafer may be prevented more reliably.

The embodiments of the present disclosure may not necessarily be limited to the configurations described above or in the modified example but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure. Optionally, some of the steps described in the above embodiments may be omitted, or new steps may be added.

In the embodiments described above, the inspection to be performed in the inspection step incudes inspecting whether the protective film 40 is formed correctly in the target region and whether the protective film 40 is dried; however, contents of the inspection are not necessarily limited to these. The inspection to be performed in the inspection step may include any inspection as long as the condition of the protective film 40 is inspected. For example, the thickness of the protective film 40 may be inspected. Moreover, data concerning the protective film 40 obtained in the inspection step may be recorded to ensure traceability. The data to be recorded may include not only the inspection results and data related thereto, but also may include any measurement results not directly related to the inspection.

In the embodiments described above, images are acquired by the image capturing unit 90 and the protective film 40 is inspected based on the acquired images; however, the inspection to be performed in the inspection step is not necessarily limited to the inspection based on images. For example, the protective film 40 may be inspected based on detected results acquired from any sensor.

In the embodiments described above, the wafer 10 is cut from the side of the back surface 16, where the ring-shaped reinforcement portion 18 is formed; however, the wafer 10 may also be cut from the side of the front surface 11, as long as the protective film 40 is formed on the surface on the side at which the laser beam is emitted.

As described above, the method for processing a wafer and the method for manufacturing device chips according to the present disclosure may reduce adhesion of debris generated by laser ablation, and are useful in the technical field of processing wafers and manufacturing device chips.

What is claimed is:

1. A processing method for processing a wafer, on a surface on one side of which a recess and a ring-shaped protrusion surrounding the recess are formed, the surface having a protective member being fixed thereon, the processing method comprising:
holding the one side of the wafer against a holder table;
forming a protective film in a region including a boundary between the recess and the protrusion on the wafer held on the holder table;
inspecting the protective film formed on the wafer; and
cutting the wafer along the boundary, in a case where the protective film passes the inspection, by irradiating the boundary with a laser beam.

2. The processing method according to claim 1, wherein, in a case where the protective film does not pass the inspection, forming the protective film on the wafer is repeated.

3. The processing method according to claim 1, further comprising drying the protective film by supplying a gas to the protective film after forming the protective film on the wafer.

4. The processing method according to claim 3, wherein drying the protective film includes supplying the gas from an outer side toward an inner side of the wafer.

5. The processing method according to claim 1, further comprising separating the protrusion from the protective member after cutting the wafer along the boundary by inserting a separating member between the protective member and the protrusion.

6. A manufacturing method for manufacturing a plurality of device chips, comprising:
holding one side of a wafer against a holder table, the wafer including a surface on the one side thereof, the surface having a recess and a ring-shaped protrusion surrounding the recess being formed thereon and a protective member being fixed thereon;
forming a protective film in a region including a boundary between the recess and the protrusion on the wafer held on the holder table;
inspecting the protective film formed on the wafer;
cutting the wafer along the boundary, in a case where the protective film passes the inspection, by irradiating the boundary with a laser beam; and
dicing a region corresponding to the recess in the wafer into the plurality of device chips after cutting the wafer along the boundary.
